(19) United States
(12) Patent Application Publication
(10) Pub. No.: US 2024/0417615 A1
(43) Pub. Date: Dec. 19, 2024

(54) THERMALLY CONDUCTIVE SHEET

(71) Applicant: SEKISUI POLYMATECH CO., LTD., Saitama (JP)

(72) Inventors: Hiroki KUDOH, Saitama-shi, Saitama (JP); Kenta KUROO, Saitama-shi, Saitama (JP); Hiroshi UMETANI, Saitama-shi, Saitama (JP)

(73) Assignee: SEKISUI POLYMATECH CO., LTD., Saitama (JP)

(21) Appl. No.: 18/706,927

(22) PCT Filed: Nov. 7, 2022
(86) PCT No.: PCT/JP2022/041365

§ 371 Date: May 2, 2024

(30) Foreign Application Priority Data
Nov. 5, 2021 (JP) 2021-181503

(51) Int. Cl. C09K 5/14; B26D 7/08; B29C 35/16; B29C 45/00; B29C 71/00; B29K 83/00; B29K 105/16; B29K 505/02; B29K 507/04; C08K 5/5419; C08L 83/04

(52) U.S. Cl. CPC C09K 5/14; C08K 5/5419; C08L 83/04; B26D 7/08; B29C 35/16; B29C 45/0013; B29C 45/0055; B29C 71/0072; B29C 2793/0027; B29C 2793/009; B29K 2083/00; B29K 2105/16; B29K 2505/02; B29K 2507/04; B29K 2995/0013; B29K 2995/0044; B29K 2995/007; C08L 2207/324

(57) ABSTRACT

A heat-conductive sheet comprising: a matrix formed of polyorganosiloxane; a material to increase hardness in low temperatures, the material having at least either one of an alkyl group having 10 or more carbon atoms and a dimethylsiloxane structure and also having a melting point of −60° C. to 23° C., thereby increasing a type OO hardness of the heat-conductive sheet, as specified in ASTM D2240, in a case where the heat-conductive sheet is cooled from room temperature to a temperature lower than room temperature; and a heat-conductive filler, the heat-conductive sheet having a type OO hardness of 50 or less at 25° C.

### TECHNICAL FIELD

The present invention relates to a heat-conductive sheet, for example, a heat-conductive sheet that is used in a state in which it is disposed between a heating element and a heat sink.

### BACKGROUND ART

In electronic devices such as computers, car parts, and mobile phones, heat sinks such as heat sinks are generally used to dissipate heat generated from heating elements such as semiconductor elements and machine parts. It is known that a heat-conductive sheet is disposed between a heating element and a heat sink for the purpose of increasing the efficiency of heat transfer to the heat sink. As the heat-conductive sheet, those including a matrix formed of silicone resin (polyorganosiloxane) are widely used in view of heat resistance, long-term reliability, and other factors. In addition, the heat-conductive sheet is required to have a followability to the heating element and the heat sink in order to enhance the conduction efficiency, and for example, it may be required to be flexible at normal temperature in order to ensure high conduction efficiency even at around normal temperature.

Conventionally, it is widely known that heat-conductive sheets are produced by slicing a molded product that has been molded into the form of a block or the like, as disclosed in PTLs 1 to 3, for example. At this time, it is necessary, for the molded product to be sliced, to have some degree of hardness to prevent deformation, etc. at the time of sheet processing to thereby achieve proper sheeting. Therefore, when producing flexible heat-conductive sheets at room temperature, for example, as disclosed in PTL 3, the molded product may be cooled and then sliced.

### CITATION LIST

### Patent Literatures

PTL1: International Publication No. WO 2016/190258
PTL2: JP 2015-015360 A
PTL3: JP 2017-141443 A

### SUMMARY OF INVENTION

### Technical Problem

However, in general, heat-conductive sheets containing a matrix formed of polyorganosiloxane are not sufficiently hardened even by cooling. Therefore, they have poor processability not only under room temperature environment but also under cooling, and even if they are cooled and then sliced, the molded product is deformed at the time of slicing, making it difficult to produce heat-conductive sheets in a practical manner.

It is therefore an object of the present invention to provide a heat-conductive sheet that includes a matrix formed of polyorganosiloxane but can still be sufficiently hardened in low temperature environment to provide good processability in low temperature environment and that is flexible at around room temperature.

### Solution to Problem

As a result of diligent studies, the inventors have found that the aforementioned problem can be solved when a heat-conductive sheet including a matrix formed of polyorganosiloxane and a heat-conductive filler further includes a predetermined material to increase hardness in low temperatures, and also has a type 00 hardness at 25° C. less than a certain value, thereby accomplishing the present invention described below. Specifically, the present invention provides [1] to [7] below.
[1] A heat-conductive sheet comprising:
   a matrix formed of polyorganosiloxane;
   a material to increase hardness in low temperatures, the material having at least either one of an alkyl group having 10 or more carbon atoms and a dimethylsiloxane structure and also having a melting point of −60° C. to 23° C., thereby increasing a type 00 hardness of the heat-conductive sheet, as specified in ASTM D2240, in a case where the heat-conductive sheet is cooled from room temperature to a temperature lower than room temperature; and
   a heat-conductive filler,
   the heat-conductive sheet having a type 00 hardness of 50 or less at 25° C.
[2] The heat-conductive sheet according to [1] above, wherein the material to increase hardness in low temperatures has a melting point of −40° C. to 5° C.
[3] The heat-conductive sheet according to [1] or [2] above, wherein the material to increase hardness in low temperatures is at least one selected from the group consisting of a hydrocarbon compound, an ester compound, a high melting point liquid silicone, and a methyl phenyl silicone.
[4] The heat-conductive sheet according to [3] above, wherein the hydrocarbon compound is liquid paraffin.
[5] The heat-conductive sheet according to any one of [1] to [4] above, wherein the heat-conductive sheet has a content of the material to increase hardness in low temperatures of 0.5 to 100 parts by mass, with respect to 100 parts by mass of the matrix.
[6] The heat-conductive sheet according to any one of [1] to [5] above, wherein the heat-conductive filler comprises an anisotropic filler.
[7] A method for producing a heat-conductive sheet, the method comprising:
   the step of obtaining an oriented molded product in a form of a block, the oriented molded product comprising: a matrix formed of polyorganosiloxane; a material to increase hardness in low temperatures, the material having at least either one of an alkyl group having 10 or more carbon atoms and a dimethylsiloxane structure and also having a melting point of −60° C. to 23° C., thereby increasing a type 00 hardness of the oriented molded product, as specified in ASTM D2240, in a case where the oriented molded product is cooled from room temperature to a temperature lower than room temperature; and a heat-conductive filler; the oriented molded product having a type 00 hardness of 50 or less at 25° C.; and
   the step of cooling the oriented molded product so as to have a type 00 hardness of greater than 50, and then cutting the oriented molded product.

### Advantageous Effects of Invention

The present invention can provide a heat-conductive sheet that includes a matrix formed of polyorganosiloxane but can still sufficiently hardened in low temperature environment to provide good processability in low temperature environment and that is flexible at around room temperature.

### DESCRIPTION OF EMBODIMENTS

### [Heat-Conductive Sheet]

Hereinafter, a heat-conductive sheet according to an embodiment of the present invention will be described in detail.

The heat-conductive sheet of the present invention comprises a matrix, a material to increase hardness in low temperatures, and a heat-conductive filler.

### <Matrix>

The matrix is a member that holds the heat-conductive filler and ensures shape retention of the heat-conductive sheet. The heat-conductive sheet in the present invention comprises a matrix formed of polyorganosiloxane. The polyorganosiloxane may be any of the condensation reaction type and the addition reaction type, and is preferably the addition reaction type because of the following reasons: a large amount of the heat-conductive filler is easily filled therein, and the curing temperature can be easily adjusted by a catalyst or the like. The matrix can be obtained, for example, by curing a curable silicone composition. The curable silicone composition may be composed, for example, of a base resin and a curing agent.

In the case where the curable silicone composition is of the addition reaction type, it preferably contains an alkenyl group-containing polyorganosiloxane as a base resin and hydrogen polyorganosiloxane as a curing agent. By using an alkenyl group-containing polyorganosiloxane and hydrogen polyorganosiloxane, the two undergo an addition reaction to form a cured product, resulting in a heat-conductive sheet with excellent shape retention, handleability, and other properties.

The curable silicone composition is preferably in a liquid form before cured. In the case where the curable silicone composition is in a liquid form before cured, a large amount of the heat-conductive filler can be easily filled therein, and also the material to increase hardness in low temperatures is easily dispersed in the curable silicone composition. Herein, a liquid form means a liquid at normal temperature (23° C.) and a pressure of 1 atm.

The polyorganosiloxane may have at least dimethylsiloxane unit. Therefore, as the polyorganosiloxane containing alkenyl group, it is preferable to use polyorganosiloxane having at least dimethylsiloxane unit. Specific examples thereof include vinyl dual-end polyorganosiloxane having dimethylsiloxane unit such as vinyl dual-end polydimethylsiloxane, vinyl dual-end dimethylsiloxane-diphenylsiloxane copolymer, vinyl dual-end dimethylsiloxane-phenylmethylsiloxane copolymer, and vinyl dual-end dimethylsiloxane-diethylsiloxane copolymer.

The hydrogen polyorganosiloxane is a compound having two or more hydrosilyl groups (SiH) and can cure the alkenyl group-containing polyorganosiloxane, which is the base resin.

Further, it is preferable that the matrix should be three-dimensionally crosslinked, in view of ensuring the shape retention of the heat-conductive sheet. Therefore, in the case of, for example, an addition reaction type, a curable silicone composition may be cured that contains at least an alkenyl group-containing polyorganosiloxane having at least three or more alkenyl groups in one molecule, or hydrogen polyorganosiloxane having at least three or more hydrogen atoms added to silicon atoms. In particular, a curable silicone composition containing at least hydrogen polyorganosiloxane having at least three or more hydrogen atoms added to silicon atoms is preferable.

### <Material to Increase Hardness in Low Temperatures>

The heat-conductive sheet of the present invention comprises a material to increase hardness in low temperatures. The material to increase hardness in low temperatures may be uniformly mixed with the matrix, and the heat-conductive filler described later may be dispersed in the mixture of the matrix and the material to increase hardness in low temperatures.

The material to increase hardness in low temperatures is a material that increases the hardness of the heat-conductive sheet in a case where the heat-conductive sheet is cooled from room temperature (23° C.) to a temperature lower than room temperature. The material to increase hardness in low temperatures contained imparts moderate hardness in low temperature environment to the heat-conductive sheet, while the heat-conductive sheet has moderate flexibility at around room temperature, and thus the processability of the heat-conductive sheet in low temperature environment can be improved. Therefore, it is possible to practically produce the heat-conductive sheet by cooling slicing, etc., the heat-conductive sheet still being flexible at around room temperature and ensuring high conduction efficiency.

The material to increase hardness in low temperatures has at least either one of an alkyl group having 10 or more carbon atoms and a dimethylsiloxane structure. Since the material to increase hardness in low temperatures has the structure described above, it has good compatibility with the matrix formed of polyorganosiloxane, preventing defects such as separation of the material to increase hardness in low temperatures from the matrix at the time of production. Therefore, the material to increase hardness in low temperatures can properly increase the hardness in low temperatures and can also provide a heat-conductive sheet with good quality.

The alkyl group here may be linear, may be a chain structure having a branched structure, may have a cyclic structure, or may be a combination of a cyclic structure and a chain structure. Also, the material to increase hardness in low temperatures may have any alkyl structure having 10 or more carbon atoms, and for example, even in the case of an unsaturated hydrocarbon linked to an alkyl structure, the alkyl structure moiety is considered an “alkyl group” herein. In the case where a compound as a whole has an aliphatic saturated hydrocarbon structure, it is considered to be an alkyl group in its entirety.

The alkyl group having 10 or more carbon atoms is preferably an alkyl group having 11 or more carbon atoms, more preferably an alkyl group having 13 carbon atoms, and further preferably an alkyl group having 15 or more carbon atoms. Although there is no particular limitation on the upper limit of the number of carbon atoms in the alkyl group having 10 or more carbon atoms, it is, for example, 50 or less, preferably 40 or less, more preferably 32 or less, and further preferably 28 or less.

The aforementioned number of carbon atoms is preferably 10 to 50, more preferably 11 to 40, further preferably 13 to 32, and particularly preferably 15 to 28.

Herein, ranges indicated by “to” mean that the ranges are from the predetermined value described before “to” to the predetermined value described after it, inclusive of both the values.

The material to increase hardness in low temperatures has a melting point of −60° C. to 23° C. If the material to increase hardness in low temperatures has a melting point of higher than 23° C., the hardness of the heat-conductive sheet at room temperature is increased, and it becomes difficult to make the heat-conductive sheet flexible at around room temperature. If the melting point is lower than −60° C., the hardness of the heat-conductive sheet does not become small unless the cooling temperature is extremely low, and it becomes difficult to achieve high processability in practical environment, and for example, it is practically difficult to produce the heat-conductive sheet by cooling slicing.

In view of ensuring flexibility at around room temperature, the melting point is preferably 15° C. or lower, more preferably 10° C. or lower, and further preferably 5° C. or lower.

Also, in view of providing good processability in practical low temperature environment, the melting point above is preferably −55° C. or higher, more preferably −40° C. or higher, and further preferably −30° C. or higher. Further, the melting point is preferably −55 to 15° C., more preferably −40 to 10° C., and further preferably −30 to 5° C.

The melting point is the temperature of the endothermic peak in the DTA curve measured by differential thermal analysis (DTA), and the details of the measurement method are as shown in Examples.

Examples of the material to increase hardness in low temperatures include a hydrocarbon compound, an ester compound, a high melting point liquid silicone, and a methyl phenyl silicone. A single type of the material to increase hardness in low temperatures may be used alone, or two or more types of them may be used in combination. These compounds do not react with the matrix in the heat-conductive sheet, and they function as plasticizers at normal temperature to improve the flexibility of the heat-conductive sheet, while they increase the hardness of the heat-conductive sheet in low temperature environment.

### (Hydrocarbon Compound)

Examples of the hydrocarbon compound used as the material to increase hardness in low temperatures include those with a melting point within the range described above and also with an alkyl group having 10 or more carbon atoms. Specific examples of the hydrocarbon compound include liquid paraffin and polyalphaolefin, of which liquid paraffin is preferable.

Liquid paraffin is, for example, an aliphatic saturated hydrocarbon compound having 12 to 36 carbon atoms, preferably having about 14 to 28 carbon atoms. The aliphatic saturated hydrocarbon compound may be linear, may be branched, or may have a cyclic structure. Also, it may be a mixture of two or more types of aliphatic saturated hydrocarbon compounds.

Polyalphaolefin is, for example, a polymer of α-olefins having 2 to 30 carbon atoms, preferably having 4 to 20 carbon atoms. Examples of the α-olefins include various butenes such as isobutene and n-butene, 1-decene, and 1-dodecene. For the polyalphaolefin, a plurality of alpha-olefins are polymerized to form an aliphatic saturated hydrocarbon moiety having 10 or more carbon atoms, and such an aliphatic hydrocarbon moiety may be an alkyl group having 10 or more carbon atoms.

In view of enhancing heat resistance, the average molecular weight of the hydrocarbon compound is preferably 200 or more, more preferably 225 or more, and further preferably 250 or more. Also, in view of the flexibility of the heat-conductive sheet, the aforementioned average molecular weight is preferably 500 or less, more preferably 350 or less, and further preferably 300 or less.

Further, the average molecular weight is preferably 200 to 500, more preferably 225 to 350, and further preferably 250 to 300. When the average molecular weight of the hydrocarbon compound is within the range described above, it is easier to achieve good compatibility with the matrix, etc. In addition, it is possible to provide good flexibility and mechanical strength of the heat-conductive sheet in a well-balanced manner.

Although not particularly limited, the density of the hydrocarbon compound is preferably 0.80 to 0.90 g/cm³, more preferably 0.82 to 0.87 g/cm³, and further preferably 0.83 to 0.86 g/cm³.

The kinematic viscosity of the hydrocarbon compound at 40° C. is preferably 100 cSt or less, preferably 70 cSt or less, and further preferably 50 cSt or less. When the kinematic viscosity is at or below the upper limit value described above, it is easier to enhance the flexibility of the heat-conductive sheet. The kinematic viscosity of the hydrocarbon compound at 40° C. is also preferably 3 cSt or more, more preferably 5 cSt or more, and further preferably 8 cSt or more. When the kinematic viscosity of the hydrocarbon compound is at or above the lower limit value described above, it is easier to suppress reduction in the mechanical strength and other properties of the heat-conductive sheet. Furthermore, when the kinematic viscosity is within the range described above, the hydrocarbon compound is more compatible with the matrix, etc.

The kinematic viscosity of the hydrocarbon compound at 40° C. is preferably 3 to 100 cSt or less, preferably 5 to 70 cSt or less, and further preferably 8 to 50 cSt or less.

### (Ester Compound)

Examples of the ester compound include ester compounds with an alkyl group having 10 or more carbon atoms. The ester compound preferably has an alkyl group having 11 to 24 carbon atoms, more preferably has an alkyl group having 13 to 20 carbon atoms, and further preferably has an alkyl group having 15 to 18 carbon atoms. Due to having an alkyl group with the number of carbon atoms described above, the ester compound tends to have improved compatibility with the matrix and also to have the melting point adjusted to a proper range.

The number of carbon atoms in the ester compound is usually 12 or more, preferably 13 or more, more preferably 15 or more, and further preferably 17 or more, and it is preferably 28 or less, more preferably 26 or less, and further preferably 24 or less. When the number of carbon atoms in the ester compound is 12 or more, the compatibility with the matrix is more likely to be enhanced. In addition, the heat-conductive sheet tends to have good heat resistance. On the other hand, when the number of carbon atoms in the ester compound is 28 or less, it is easier to maintain good compatibility with the matrix and to lower the melting point of the ester compound.

The number of carbon atoms in the ester compound is preferably 13 to 28, more preferably 15 to 26, and further preferably 17 to 24.

Also, in view of the melting point in a proper range, heat resistance, and enhanced compatibility with the matrix, the molecular weight of the ester compound is preferably 200 or more, more preferably 210 or more, and further preferably 270 or more, and it is preferably 430 or less, more preferably 400 or less, and further preferably 380 or less.

The molecular weight of the ester compound is preferably 200 to 430, more preferably 210 to 400, and further preferably 270 to 380.

The ester compound may be a monoester having one ester group, or it may be one having two or more ester groups such as a diester. However, in view of tendency to have a lower melting point and in view of compatibility with the matrix, etc., it is preferably a monoester. In particular, in view of having a lower melting point to ensure flexibility at normal temperature while improving processability in low temperature environment, the ester compound is preferably a compound represented by the following formula (1).

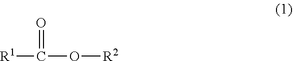

wherein R¹ and R² are hydrocarbon groups, and at least either one of R¹ and R² is an alkyl group having 10 or more carbon atoms.

In formula (1), the hydrocarbon groups in R¹ and R² have 1 to 26 carbon atoms, for example. The hydrocarbon groups in R¹ and R² are preferably both alkyl groups. R¹ and R² may be linear, may be a chain structure including a branched structure, or may include a cyclic structure, but it is preferable that they should be a chain structure without a cyclic structure.

At least either one of R¹ and R² is an alkyl group having 10 or more carbon atoms, and it is preferable that at least R¹ should be an alkyl group having 10 or more carbon atoms. The alkyl group having 10 or more carbon atoms preferably has 11 or more carbon atoms, more preferably 13 or more carbon atoms, and further preferably 15 or more carbon atoms, and also preferably has 24 or less carbon atoms, more preferably 20 or less carbon atoms, and further preferably 18 or less carbon atoms.

At least either one of R¹ and R² is preferably an alkyl group having 11 to 24 carbon atoms, more preferably an alkyl group having 13 to 20 carbon atoms, and further preferably an alkyl group having 15 to 18 carbon atoms.

The total number of carbon atoms in R¹ and R² in formula (1) is 11 or more, preferably 12 or more, more preferably 14 or more, and further preferably 16 or more, and it is preferably 27 or less, more preferably 25 or less, and further preferably 23 or less.

The total number of carbon atoms in R¹ and R² in formula (1) is preferably 12 to 27 or more, more preferably 14 to 25, and further preferably 16 to 23.

For R¹ and R², it is preferable that either one of them should be an alkyl group having 10 or more carbon atoms and that the other should be an alkyl group having 9 or less carbon atoms. This reduces the effect of polarity of the ester group and makes the ester compound more compatible with the matrix. Also, in view of improving the compatibility of the ester compound with the matrix, it is preferable that both R¹ and R² should be alkyl groups having 18 or less carbon atoms.

R¹ is preferably an alkyl group having 10 or more carbon atoms, more preferably an alkyl group having 11 or more carbon atoms, and further preferably an alkyl group having 15 or more carbon atoms, and it is also preferably an alkyl group having 23 or less carbon atoms, more preferably 19 or less carbon atoms, and further preferably 17 or less carbon atoms.

R¹ is preferably an alkyl group having 10 to 23 carbon atoms, more preferably an alkyl group having 11 to 19 carbon atoms, and further preferably an alkyl group having 15 to 17 carbon atoms.

Meanwhile, R² is, for example, an alkyl group having 1 or more carbon atoms, preferably an alkyl group having 2 or more carbon atoms, and more preferably an alkyl group having 3 or more carbon atoms, and it is also preferably an alkyl group having 16 or less carbon atoms, more preferably an alkyl group having 12 or less carbon atoms, and further preferably an alkyl group having 8 or less carbon atoms.

R² is preferably an alkyl group having 1 to 16 carbon atoms, more preferably an alkyl group having 2 to 12 carbon atoms, and further preferably an alkyl group having 3 to 8 carbon atoms.

When R¹ and R² are alkyl groups having such a number of carbon atoms, the ester compound tends to have a lower melting point, and both flexibility at normal temperature and processability in low temperature environment are thus more likely to be good. In addition, the ester compound tends to have good compatibility with the matrix.

As the ester compound in the present invention, the compounds described above can be used without any particular restriction, and specific examples thereof include cetyl 2-ethylhexanoate (melting point −5° C.), methyl laurate (melting point 5° C.), isopropyl myristate (melting point 5° C.), isopropyl palmitate (melting point 11° C.), 2-ethylhexyl palmitate (melting point 2° C.), and 2-ethylhexyl stearate (melting point 10° C.).

### (High Melting Point Liquid Silicone)

Examples of the high melting point liquid silicone include high melting point liquid silicones having a dimethylsiloxane structure. The high melting point liquid silicone is a silicone that has a melting point in the range of −60° C. to 23° C. and is in a liquid form at 25° C. Also, the high melting point liquid silicone is a non-reactive silicone and does not react with the matrix in the heat-conductive sheet as described above.

The high melting point liquid silicone may be linear or may be branched. The high melting point liquid silicone having a branched shape is also called a silicone resin, and for example, it preferably has a T unit (RSiO_{3/2} unit, which has three oxygen atoms bonded to the Si atom: R is a hydrocarbon group, for example), in addition to a D unit (R₂SiO_{2/2} unit: R is a hydrocarbon group, for example) such as dimethylsiloxy unit. Also, the larger the molecular weight of the high melting point liquid silicone, the higher its melting point. In the high melting point liquid silicone, the number of branches, molecular weight, etc. may be adjusted such that the melting point is within the range described above. Examples of the high melting point liquid silicone include linear dimethyl silicones, and for example, it may be a linear high molecular weight silicone with a kinematic viscosity of 1,000,000 to 4,000,000 cSt at 25° C. (for example, a melting point of about −45° C. to −30° C.).

### (Methyl Phenyl Silicone)

The methyl phenyl silicone is a non-reactive silicone having a structural formula in which methyl groups are partially replaced by phenyl groups as side chains on the silicon atoms in the polysiloxane bonds, and does not react with the matrix as described above. The methyl phenyl silicone is a compound having, for example, at least either one of methyl phenyl siloxane unit and diphenyl siloxane unit, and dimethyl siloxane unit.

The methyl phenyl silicone to be added can be in an oil form or in an oligomeric form, but it is preferable to add it in an oil form in view of easy compatibility with the matrix. The kinematic viscosity of the methyl phenyl silicone is preferably in the range of 10 to 100,000 cSt at 25° C., and in view of dispersibility in the matrix, more preferably in the range of 100 to 1000 cSt. The kinematic viscosity shall be measured in accordance with JIS Z 8803:2011.

Among methyl phenyl silicones, it is preferable to use a methyl phenyl silicone oil with a refractive index of 1.427 or more as measured in accordance with JIS K 0062:1992. The refractive index is an indicator of the amount of phenyl groups in the methyl phenyl silicone oil. Methyl phenyl silicone oils with a high refractive index are generally considered to have a larger content of phenyl groups than methyl phenyl silicone oils with a low refractive index. For example, the refractive index of the methyl phenyl silicone can be determined as follows: pressure is applied to the heat-conductive composition or heat-conductive sheet with a roller, etc., and after isolating the oil that has been bled out, measurement is performed by a method in accordance with JIS K 0062:1992.

A single type of the material to increase hardness in low temperatures may be used alone, or two or more types of them may be used in combination.

Among the above, the material to increase hardness in low temperatures is preferably at least one selected from the group consisting of the hydrocarbon compound, the ester compound, and the high melting point liquid silicone. When any of these materials to increase hardness in low temperatures is used, bleeding out of the material to increase hardness in low temperatures is prevented even after long-term use, and the heat-conductive sheet has good reliability.

The material to increase hardness in low temperatures may be other than those containing both the hydrocarbon compound and the methyl phenyl silicone. It may also be other than those containing at least one of liquid paraffin and methyl phenyl silicone.

The heat-conductive sheet preferably has a content of the material to increase hardness in low temperatures of 0.5 to 100 parts by mass, with respect to 100 parts by mass of the matrix. When the content of the material to increase hardness in low temperatures is 0.5 parts by mass or more, the material to increase hardness in low temperatures can significantly increase hardness in low temperature environment and provide good processability in low temperature environment. Also, when the content is 100 parts by mass or less, moderate mechanical strength is imparted to the heat-conductive sheet and shape retention at around normal temperature is easily ensured. In addition, even after long-term use, bleeding out of the material to increase hardness in low temperatures is suppressed, and the heat-conductive sheet tends to have good reliability.

From these viewpoints, the content of the material to increase hardness in low temperatures is more preferably 2 parts by mass or more, further preferably 5 parts by mass or more, and furthermore preferably 10 parts by mass or more, and it is more preferably 65 parts by mass or less, further preferably 50 parts by mass or less, and furthermore preferably 30 parts by mass or less, with respect to 100 parts by mass of the matrix.

The content of the material to increase hardness in low temperatures is preferably 2 to 65 parts by mass, more preferably 5 to 50 parts by mass, and further preferably 10 to 30 parts by mass, with respect to 100 parts by mass of the matrix.

Although the total of the volume filling rate of the material to increase hardness in low temperatures and that of the matrix in the heat-conductive sheet is not particularly limited, it is preferably 10 to 70 vol %, more preferably 12 to 50 vol %, and further preferably 15 to 39 vol %.

### <Heat-Conductive Filler>

The heat-conductive sheet of the present invention further comprises the heat-conductive filler. Preferably, the heat-conductive filler is dispersed in the binder component that is a mixture of the matrix and the material to increase hardness in low temperatures, and is held by the binder component.

The heat-conductive filler may be an anisotropic filler or a non-anisotropic filler, or both of them may be used in combination. The heat-conductive filler preferably includes at least an anisotropic filler, more preferably includes both of an anisotropic filler and a non-anisotropic filler. The heat-conductive sheet tends to enhance the thermal conductivity when containing an anisotropic filler.

The anisotropic filler are preferably oriented in one direction, and specifically, preferably oriented in the thickness direction of the heat-conductive sheet. When the anisotropic filler is oriented in the thickness direction, the thermal conductivity in the thickness direction tends to be enhanced.

The state in which the anisotropic filler is oriented means that the long-axis direction of the anisotropic filler is in a predetermined direction. Further, when the anisotropic filler is oriented in the thickness direction, the long-axis direction is not necessarily strictly parallel to the thickness direction, and the long-axis direction inclined to some extent in the thickness direction is also considered to be oriented in the thickness direction. Specifically, those with the long-axis direction inclined at about less than 200 are also considered as an anisotropic filler oriented in the thickness direction, and when such anisotropic filler are predominant (for example, over 60%, preferably over 80%, with respect to the total number of particles of the anisotropic filler) in the heat-conductive sheet, they are considered to be oriented in the thickness direction.

Further, in the above description, the anisotropic filler has been explained on the premise that they are oriented in the thickness direction; however, the same applies to the case where they are oriented in another direction.

In view of enhancing thermal conductivity, the content of the heat-conductive filler is preferably 150 parts by mass or more, more preferably 200 parts by mass or more, and further preferably 300 parts by mass or more, with respect to 100 parts by mass of a total of the matrix and the material to increase hardness in low temperatures.

Also, in view of preventing a higher viscosity of the heat-conductive composition than necessary, the content of the heat-conductive filler is preferably 3000 parts by mass or less, more preferably 2000 parts by mass or less, and further preferably 1000 parts by mass or less, with respect to 100 parts by mass of a total of the matrix and the material to increase hardness in low temperatures.

The content of the heat-conductive filler is preferably 150 to 3000 parts by mass, more preferably 200 to 2000 parts by mass, and further preferably 300 to 1000 parts by mass, with respect to 100 parts by mass of a total of the matrix and the material to increase hardness in low temperatures. When the content of the heat-conductive filler are 150 parts by mass or more, a certain thermal conductivity can be imparted to the heat-conductive sheet. When the content is 3000 parts by mass or less, the heat-conductive filler can be appropriately dispersed in the binder component. Further, it is possible to prevent the viscosity of the heat-conductive composition, which will be described below, from increasing higher than necessary.

Further, the volume filling rate of the heat-conductive filler is preferably 30 to 85 vol %, more preferably 50 to 83 vol %, further preferably 61 to 80 vol %, with respect to the total amount of the heat-conductive sheet. When the volume filling rate is the aforementioned lower limit or more, a certain thermal conductivity can be imparted to the heat-conductive sheet. When the volume filling rate is the upper limit or less, the heat-conductive sheet is easily produced.

### (Anisotropic Filler)

The anisotropic filler is a filler that has an anisotropic shape and is capable of being oriented. Examples of the anisotropic filler include fiber materials and flaky materials. The anisotropic filler has a high aspect ratio, specifically, an aspect ratio of over 2, and preferably has an aspect ratio of 5 or more. An anisotropic filler having the aspect ratio over 2 easily orients in one direction such as the thickness direction or the like, and thus the thermal conductivity in the one direction such as the thickness direction or the like of the heat-conductive sheet is easily enhanced. Further, the upper limit of the aspect ratio is not specifically limited, but is practically 100.

The aspect ratio is preferably greater than 2 and 100 or less, and more preferably 5 to 100.

The aspect ratio is the ratio of the length in the long-axis direction to the length in the short-axis direction of the anisotropic filler. The aspect ratio means the fiber length/the fiber diameter when it is a fiber material, and means the length in the long-axis direction of a flake/the thickness thereof when it is a flaky material.

The content of the anisotropic filler in the heat-conductive sheet is preferably 10 to 500 parts by mass, more preferably 30 to 300 parts by mass, and further preferably 50 to 250 parts by mass, with respect to 100 parts by mass of a total of the matrix and the material to increase hardness in low temperatures.

When the content of the anisotropic filler is 10 parts by mass or more, the thermal conductivity is easily enhanced. Also, when it is 500 parts by mass or less, the viscosity of the heat-conductive composition, which will be described below, tends to be appropriate, and the orientation of the anisotropic filler is improved. Furthermore, the dispersibility of the anisotropic filler in the matrix is also improved.

The content of the anisotropic filler in the heat-conductive sheet is preferably 10 parts by mass or more, more preferably 30 parts by mass or more, and further preferably 50 parts by mass or more.

The content of the anisotropic filler in the heat-conductive sheet is preferably 500 parts by mass or less, more preferably 300 parts by mass or less, and further preferably 250 parts by mass or less.

In the case where the anisotropic filler is a fiber material, the average fiber length is preferably 10 to 500 μm, more preferably 20 to 350 μm, further preferably 50 to 300 μm. When fibers of an anisotropic filler have an average fiber length of 10 μm or more, they come into contact with each other appropriately inside the heat-conductive sheet, and therefore, a heat transfer path is ensured and the thermal conductivity of the heat-conductive sheet is improved.

On the other hand, when the anisotropic filler has an average fiber length of 500 μm or less, the bulk of the anisotropic filler is low and a large amount thereof can be filled in the binder component.

The average fiber length of fiber materials is preferably shorter than the thickness of the heat-conductive sheet. The average fiber length shorter than the thickness prevents the fiber materials from protruding from the surface of the heat-conductive sheet more than necessary.

The average fiber length can be calculated by observing the anisotropic filler with a microscope. More specifically, the fiber lengths of any 50 fibers of the anisotropic filler are measured, for example, using an electron microscope or optical microscope, and the average (arithmetic mean) thereof can be taken as an average fiber length.

In the case where the anisotropic filler is a flaky material, the average particle size is preferably 10 to 400 μm, more preferably 15 to 300 μm, further preferably 20 to 200 μm. When flakes of the anisotropic filler have an average particle size of 10 μm or more, they come into contact with each other in the heat-conductive sheet, and therefore a heat transfer path is ensured and the thermal conductivity of the heat-conductive sheet is improved.

When the anisotropic filler has an average particle size of 400 μm or less, the bulk of the heat-conductive sheet to be low, so that a large amount of the anisotropic filler can be filled in the binder component.

The average particle size of the flaky material can be calculated by observing the anisotropic filler with a microscope and determining the major diameter as a diameter. More specifically, the major diameters of any 50 flakes of anisotropic filler are measured, for example, with an electron microscope or optical microscope, and the average (arithmetic mean) thereof can be taken as an average particle size.

As the anisotropic filler, any known material having a thermal conductivity may be used. The anisotropic filler is preferably diamagnetic in the case where it is to be oriented by the magnetic field orientation, as will be described below. The anisotropic filler may not be diamagnetic in the case where it is to be oriented by fluidized orientation or not oriented.

Specific examples of the anisotropic filler include carbon materials typified by carbon fibers and flaky carbon powder, metal materials typified by metal fibers, and metal oxides, boron nitride, metal nitride, metal carbide, metal hydroxide, and polyparaphenylene benzoxazole fibers. Among these, carbon materials are preferable in view of having a small specific gravity and a good dispersibility in the binder component. Among them, graphitized carbon materials having a high thermal conductivity are more preferable. A graphitized carbon material is diamagnetic when the graphite planes are aligned in a predetermined direction.

Boron nitride is also preferable as the anisotropic filler. Boron nitride is preferably used in the form of a flaky material, but is not limited thereto. The flaky boron nitride may be agglomerated or may not be agglomerated, but the flaky boron nitride is preferably partially or fully not agglomerated. The boron nitride or the like is also diamagnetic when the crystal planes are aligned in a predetermined direction.

The anisotropic filler generally have a thermal conductivity in the anisotropic direction (that is, long-axis direction) of 30 W/m·K or more, preferably 60 W/m·K or more, more preferably 100 W/m·K or more, further preferably 200 W/m·K or more, without specific limitation. The upper limit of the thermal conductivity of the anisotropic filler is not specifically limited, but is, for example, 2000 W/m·K or less. The thermal conductivity can be measured by the laser flash method or the like.

A single type of the anisotropic filler may be used alone, or two or more types of them may be used in combination. For example, at least two anisotropic fillers having different average particle sizes or average fiber lengths may be used as the anisotropic filler. It is considered that, when the anisotropic fillers having different sizes are used, particles of the small anisotropic filler enter between particles of the relatively large anisotropic filler, so that the binder component can be filled with the anisotropic fillers at a high density, and the heat conduction efficiency can thus be enhanced.

The carbon fiber used as the anisotropic filler is preferably a graphitized carbon fiber. Flaky graphite powder is preferably flaky carbon powder. It is also preferable to use the graphitized carbon fiber and the flaky graphite powder in combination as the anisotropic filler.

The graphitized carbon fiber has graphite crystal planes aligned in the fiber axis direction and thus has high thermal conductivity in the fiber axis direction. Therefore, the thermal conductivity in a specific direction can be enhanced by aligning the fiber axis directions in a predetermined direction. The flaky graphite powder has graphite crystal planes aligned in the plane direction of the flake surface and thus has high thermal conductivity in the plane direction. Therefore, the thermal conductivity in a specific direction can be enhanced by aligning the flake surfaces in a predetermined direction. The graphitized carbon fiber and flaky graphite powder each preferably have a high degree of graphitization.

As the graphitized carbon materials such as graphitized carbon fibers and flaky graphite powder described above, graphitized products of the following raw materials can be used. Examples of the raw materials include condensed polycyclic hydrocarbon compounds such as naphthalene, PAN (polyacrylonitrile), and condensed heterocyclic compounds such as pitch and the like. In particular, graphitized mesophase pitch, polyimide, or polybenzazole having a high degree of graphitization is preferably used. For example, when mesophase pitch is used, the pitch is oriented in the fiber axis direction due to its anisotropy in the spinning step, which will be described below, to give graphitized carbon fibers having excellent thermal conductivity in the fiber axis direction.

The form of the mesophase pitch used for the graphitized carbon fiber is not specifically limited, as long as it can be spun, and the mesophase pitch may be used alone or in combination with another raw material. However, use of the mesophase pitch alone, or in other words, a graphitized carbon fiber with a mesophase pitch content of 100% is most preferable in view of high thermal conductivity, spinnability, and quality stability.

The graphitized carbon fibers to be used may be those obtained by sequentially performing spinning, infusibilization, and carbonization, pulverizing or cutting into a predetermined particle size, and then graphitizing, or those obtained by carbonizing, pulverizing or cutting, and then graphitizing. In the case where pulverizing or cutting is performed before graphitization, a graphitized carbon fiber with a further improved thermal conductivity can be obtained, since polycondensation reaction and cyclization reaction are likely to proceed during graphitization on the surface newly exposed by pulverization, to enhance the degree of graphitization. On the other hand, in the case where the spun carbon fiber is pulverized after graphitization, the carbon fiber after graphitization is rigid and thus easy to pulverize, and carbon fiber powder having a relatively narrow fiber length distribution can be obtained by pulverization in a short time.

The average fiber length of the graphitized carbon fiber is preferably 10 to 500 μm, more preferably 20 to 350 μm, further preferably 50 to 300 μm, as mentioned above. The aspect ratio of each graphitized carbon fiber is over 2, preferably 5 or more, as mentioned above. The thermal conductivity of the graphitized carbon fiber is not specifically limited, but the thermal conductivity in the fiber axis direction is preferably 400 W/m·K or more, more preferably 800 W/m·K or more.

In the case where the heat-conductive sheet contains the anisotropic filler, the anisotropic filler may be exposed or may not be exposed on the sheet surface, but are preferably exposed. The sheet surface of the heat-conductive sheet can be a non-adhesive surface due to exposure of the anisotropic filler. The heat-conductive sheet serves as the main surface of the sheet, and the anisotropic filler may be exposed on any one of both faces of the sheet or may be exposed on both faces. In the case where the heat-conductive sheet has a non-adhesive sheet surface, it can be slid when it is installed into an electronic device or the like, improving the installability.

### (Non-Anisotropic Filler)

The non-anisotropic filler is a material that imparts thermal conductivity to the heat-conductive sheet when used alone or together with the anisotropic filler. Particularly, when used in combination with the anisotropic filler oriented in one direction, the non-anisotropic filler can intervene in the gap between particles of the oriented anisotropic filler, to further increase the thermal conductivity. The non-anisotropic filler is a filler that has substantially no anisotropy in shape and is not oriented in a predetermined direction even under an environment in which anisotropic filler is oriented in a predetermined direction, such as under the generation of magnetic force lines, the action of shear force or the like, which will be described below.

The non-anisotropic filler has an aspect ratio of 2 or less, preferably 1.5 or less. When used in combination with the anisotropic filler, the non-anisotropic filler having such a low aspect ratio is likely to be positioned in the gaps between the anisotropic filler and thus tends to improve the thermal conductivity. Further, the non-anisotropic filler having an aspect ratio of 2 or less can prevent increase of the viscosity of the heat-conductive composition, which will be described below, to achieve high filling rate.

Specific examples of the non-anisotropic filler include metals, metal oxides, metal nitrides, metal hydroxides, carbon materials, and oxides, nitrides, and carbides of others than metals. Examples of the shape of the non-anisotropic filler include spherical or amorphous powder.

For the non-anisotropic filler, examples of the metals include aluminum, copper, and nickel; examples of the metal oxides include aluminum oxide typified by alumina, magnesium oxide, and zinc oxide; and examples of the metal nitrides include aluminum nitride. Examples of the metal hydroxides include aluminum hydroxide. Examples of the carbon materials include spherical graphite. Examples of the oxides, nitrides, and carbides of others than metals include quartz, boron nitride, and silicon carbide.

Among these, aluminum oxide and aluminum are preferable, in view of their high thermal conductivity and availability of spherical materials.

The non-anisotropic fillers described above may be used singly or in combination of two or more.

The average particle size of the non-anisotropic filler is, for example, 0.1 to 200 μm. For example, when used in combination with the anisotropic filler, the average particle size of the non-anisotropic filler is preferably 0.1 to 50 μm, more preferably 0.5 to 35 μm, further preferably 1 to 15 μm. When the average particle size is 50 μm or less, defects such as disturbing the orientation of the anisotropic filler are less likely to occur, even when used in combination with the anisotropic filler. When the average particle size is 0.1 μm or more, the non-anisotropic filler has a specific surface area not increased more than necessary, and even when such a non-anisotropic filler is contained in a large amount, the viscosity of the heat-conductive composition is difficult to increase and a large amount of the non-anisotropic filler is easily filled.

As the non-anisotropic filler, at least two non-anisotropic fillers having different average particle sizes may be used, for example.

When using the non-anisotropic filler(s) singly as the heat-conductive filler, the average particle size is preferably 0.1 to 200 μm, more preferably 0.5 to 100 μm, further preferably 1 to 70 μm. In this case, two or more non-anisotropic fillers having different average particle sizes are preferably used in combination, in view of enhancing the thermal conductivity of the heat-conductive sheet.

The average particle size of the non-anisotropic filler can be measured through observation with an electron microscope or the like. More specifically, the particle sizes of any 50 particles of the non-anisotropic filler are measured, for example, using an electron microscope or optical microscope, and the average (arithmetic mean) thereof can be taken as an average particle size.

In view of improving thermal conductivity, the content of the non-anisotropic filler is preferably 50 parts by mass or more, more preferably 100 parts by mass or more, and further preferably 200 parts by mass or more, with respect to 100 parts by mass of a total of the matrix and the material to increase hardness in low temperatures. Also, in view of preventing the heat-conductive composition from having a higher viscosity than necessary, the content of the non-anisotropic filler is preferably 2500 parts by mass or less, more preferably 1500 parts by mass or less, and further preferably 750 parts by mass or less, with respect to 100 parts by mass of a total of the matrix and the material to increase hardness in low temperatures.

The content of the non-anisotropic filler is preferably 50 to 2500 parts by mass, more preferably 100 to 1500 parts by mass, and further preferably 200 to 750 parts by mass, with respect to 100 parts by mass of a total of the matrix and the material to increase hardness in low temperatures. When it is 50 parts by mass or more, the thermal conductivity of the heat-conductive sheet can be improved. When it is 2500 parts by mass or less, the non-anisotropic filler are appropriately dispersed in the binder component, and the effect of enhancing the thermal conductivity according to the content can be obtained. Also, the viscosity of the heat-conductive composition can be prevented from increasing more than necessary.

The mass ratio of the content of the non-anisotropic filler to the content of the anisotropic filler is not specifically limited but is preferably 0.5 to 5, more preferably 1 to 3, preferably 1.1 to 2.5. When the mass ratio is within the aforementioned range, particles of the non-anisotropic filler can be appropriately filled between particles of the anisotropic filler to form an efficient heat transfer path, and thus the thermal conductivity of the heat-conductive sheet can be furthermore improved.

### <Additives>

The heat-conductive sheet may further contain various additives, as long as the functions of the heat-conductive sheet are not impaired. Examples of the additives include at least one or more selected from dispersants, coupling agents, pressure-sensitive adhesives, flame retardants, antioxidants, colorants, and anti-settling agents. When curing the curable silicone composition as mentioned above, a curing catalyst or the like to accelerate curing may be contained as an additive. Examples of the curing catalyst include a platinum catalyst.

Also, the heat-conductive composition may contain a compatible substance, as will be described below. The compatible substance may volatilize in the process of producing the heat-conductive sheet so as not to remain, or the compatible substance contained may at least partially remain, in the heat-conductive sheet. The heat-conductive sheet may further contain a curable resin other than the matrix, as long as the functions of the heat-conductive sheet are not impaired.

### [Type OO Hardness of Heat-Conductive Sheet]

As described above, the heat-conductive sheet has flexibility at normal temperature. Hardness is an indicator of flexibility. The heat-conductive sheet of the present invention has a type OO hardness of 50 or less at 25° C. When the heat-conductive sheet has a type OO hardness of greater than 50, its followability to surrounding members such as heating element and heat sink may be insufficient at room temperature, and the performance of a heat-conductive sheet may not be fully delivered at temperatures around room temperature.

In view of enhancing the followability of the heat-conductive sheet to surrounding members to exhibit excellent thermal conductivity even at temperatures around room temperature, the type OO hardness is preferably 45 or less, more preferably 40 or less, further preferably 30 or less, and most preferably 25 or less.

The type OO hardness of the heat-conductive sheet is preferably 5 or more, more preferably 10 or more, and further preferably 15 or more. When the type OO hardness is 5 or more, the heat-conductive sheet is unlikely to lose elasticity and is thus more likely to ensure shape retention that allows it to return to the original state even when compressed. In addition, it is easier to prevent components such as the material to increase hardness in low temperatures contained in the heat-conductive sheet from bleeding out.

The type OO hardness is preferably 5 to 45, more preferably 10 to 40, and further preferably 15 to 30.

The type OO hardness is the hardness of a test piece with a thickness of 10 mm in an environment at 25° C., measured by the method specified in ASTM D2240. Specifically, in the case where the thickness of the heat-conductive sheet is less than 10 mm, a plurality of heat-conductive sheets, with the smallest number of sheets overlapped such that the total thickness is 10 mm or more, are used as a test piece to measure the hardness.

The thickness of the heat-conductive sheet is not specifically limited, and the thickness may be appropriately set according to the shape and application of the electronic device on which the heat-conductive sheet is mounted, and the thickness is, for example, in the range of 0.1 to 5 mm.

### [Method for Producing Heat-Conductive Sheet]

The method for producing the heat-conductive sheet of the present invention is not particularly limited, and the heat-conductive sheet can be obtained by obtaining a molded product formed by curing the heat-conductive composition, such as oriented molded product, and then cutting the molded product.

This production method includes, for example, the following step X, step Y, and step Z:
Step X: the step of mixing at least a matrix precursor for forming a matrix, a material to increase hardness in low temperatures, and a heat-conductive filler, to obtain a heat-conductive composition,
Step Y: the step of curing the heat-conductive composition obtained in step X,
Step Z: the step of cutting the heat-conductive composition cured in step Y (molded product).

Hereinafter, each step will be described in detail.

### (Step X)

In step X, at least a matrix precursor, a material to increase hardness in low temperatures, and a heat-conductive filler are mixed to obtain a heat-conductive composition. The matrix precursor comprises components before cured that is to constitute the matrix, and the curable silicone composition described above or the like may be used.

Additives other than these components may be further mixed with the heat-conductive composition, and a compatible substance may also be further mixed. The compatible substance is a substance that is compatible to or dissolved in the material to increase hardness in low temperatures and the matrix precursor. The material to increase hardness in low temperatures may not have sufficiently high compatibility to the matrix, but even in such a case, the use of the compatible substance allows it to be uniformly mixed in the matrix.

In step X, the mixing method and the mixing order are not specifically limited, as long as a heat-conductive composition can be obtained by mixing the aforementioned components. The matrix precursor, the material to increase hardness in low temperatures, and the heat-conductive filler, as well as the compatible substance and any other components to be added as required, may be appropriately mixed in any order, to obtain a heat-conductive composition.

The curable silicone composition is, for example, composed of a base resin and a curing agent, as mentioned above, and in such a case, the base resin, the curing agent, the material to increase hardness in low temperatures, and the heat-conductive filler, as well as the compatible substance and any other components added as required, may be mixed in any order, to obtain a heat-conductive composition.

The material to increase hardness in low temperatures may be dissolved in the compatible substance before being mixed with the matrix precursor such as curable silicone composition, and other components. In this case, a heat-conductive composition may be obtained by mixing the mixture of the material to increase hardness in low temperatures and the compatible substance, the matrix precursor (for example, the base resin and the curing agent of the curable silicone composition), the heat-conductive filler, and any other components added as required, in any order.

In the case where the material to increase hardness in low temperatures is dissolved in the compatible substance in step X in this way, it is easier for the material to increase hardness in low temperatures to be mixed even more uniformly in the matrix.

In the case where the material to increase hardness in low temperatures is dissolved in the compatible substance, they may be appropriately heated. Although the heating temperature at this time is not particularly limited, they may be heated to, for example, 40° C. or higher for dissolution. In the case where the compatible substance is mixed in the base resin and the curing agent, the upper limit of the heating temperature may be a temperature at which the curable silicone composition does not substantially cure in the process of mixing.

The heating temperature may also be a temperature at which the compatible substance is difficult to volatilize, and may be, for example, 80° C. or lower for dissolution.

### <Compatible Substance>

The compatible substance is preferably a substance that is dissolved in the material to increase hardness in low temperatures and is also compatible with the matrix precursor such as curable silicone composition. The compatible substance is preferably a substance that is liquid at normal temperature (23° C.) and a pressure of 1 atm. The compatible substance is, for example, a component that volatilizes by heating at about 50 to 180° C. in step Y. Since the compatible substance volatilizes by heating at the time of the curing, the content of the heat-conductive filler in the heat-conductive sheet can be increased. Further, the heat-conductive composition has a reduced viscosity due to containing the compatible substance. Therefore, the amount of the heat-conductive filler to be mixed are easily increased, and further the anisotropic filler is easily oriented in a predetermined direction by magnetic field orientation or the like, which will be described below.

Examples of the compatible substance include alkoxysilane compounds, hydrocarbon solvents, and alkoxysiloxane compounds. Since these compounds can enhance the solubility or compatibility to the material to increase hardness in low temperatures and the matrix precursor, the dispersibility of the material to increase hardness in low temperatures in the matrix precursor can be enhanced in the heat-conductive composition. Thus, the material to increase hardness in low temperatures is appropriately dispersed also in the heat-conductive sheet, and as a result, the shape retention, the reliability, the flexibility, and other properties are easily ensured.

The compatible substance may be used singly or in combination of two or more.

The compatible substance to be used is preferably an alkoxysilane compound. In the case where the alkoxysilane compound is used, the appearance is improved, and specifically, air voids or the like are not seen in the surface of the heat-conductive sheet obtained by curing. In addition, the dispersibility of the heat-conductive filler can also be enhanced.

The alkoxysilane compound to be used as the compatible substance is a compound having a structure in which, among the 4 bonds from a silicon atom (Si), 1 to 3 bonds each attach to an alkoxy group, and the residual bonds each attach to an organic substituent. The alkoxysilane compound, which has the alkoxy group(s) and the organic substituent(s), can enhance the dispersibility of the material to increase hardness in low temperatures in the matrix precursor.

Examples of the alkoxy group of the alkoxysilane compound include methoxy groups, ethoxy groups, protoxy groups, butoxy groups, pentoxy groups, and hexatoxy groups. In the heat-conductive composition, the alkoxysilane compound may be contained in the form of a dimer.

Among such alkoxysilane compounds, an alkoxysilane compound having at least either one of a methoxy group and an ethoxy group is preferable, in view of the availability. The number of alkoxy groups in the alkoxysilane compound is preferably 2 or 3, more preferably 3, in view of the compatibility, the solubility, and the like, with the matrix precursor and the material to increase hardness in low temperatures. Specifically, the alkoxysilane compound is preferably at least one selected from trimethoxysilane compounds, triethoxysilane compounds, dimethoxysilane compounds, and diethoxysilane compounds.

Examples of the functional group contained in the organic substituent of the alkoxysilane compound include an acryloyl group, an alkyl group, a carboxyl group, a vinyl group, a methacryl group, an aromatic group, an amino group, an isocyanate group, an isocyanurate group, an epoxy group, a hydroxyl groups, and a mercapto group. Here, when using a platinum catalyst as a curing catalyst of the curable silicone composition, an alkoxysilane compound that is difficult to affect the curing reaction of polyorganosiloxane is preferably selected and used. Specifically, when using an addition reaction type polyorganosiloxane with a platinum catalyst, the organic substituent of the alkoxysilane compound is preferably free from an amino group, an isocyanate group, an isocyanurate group, a hydroxyl group, or a mercapto group.

The alkoxysilane compound preferably contains an alkylalkoxysilane compound having an alkyl group bonded to a silicon atom, that is, an alkoxysilane compound having an alkyl group as an organic substituent, in view of enhancing the dispersibility of the material to increase hardness in low temperatures in the matrix. Accordingly, a dialkyl dialkoxysilane compound and an alkyltrialkoxysilane compound are preferable, and among them, an alkyltrialkoxysilane compound is preferable.

The number of carbon atoms of the alkyl group bound to the silicon atom may be, for example, 1 to 16. In the trialkoxysilane compound such as trimethoxysilane compounds triethoxysilane compounds and the like, the number of carbon atoms of the alkyl group is preferably 6 or more, further preferably 8 or more, and preferably 12 or less, more preferably 10 or less, in view of enhancing the dispersibility of the material to increase hardness in low temperatures.

In the dialkoxysilane compound such as dimethoxysilane compounds and diethoxysilane compounds, the number of carbon atoms of the alkyl group may be 1 or more, and is preferably 10 or less, more preferably 6 or less, further preferably 4 or less, in view of enhancing the dispersibility of the material to increase hardness in low temperatures.

Examples of the alkyl group-containing alkoxysilane compound include methyltrimethoxysilane, dimethyldimethoxysilane, diethyldimethoxysilane, trimethylmethoxysilane, methyltriethoxysilane, dimethyldiethoxysilane, ethyltrimethoxysilane, n-propyltrimethoxysilane, di-n-propyldimethoxysilane, di-n-propyldiethoxysilane, isobutyltrimethoxysilane, isobutyltriethoxysilane, isobutyltrimethoxysilane, isobutyltriethoxysilane, n-hexyltrimethoxysilane, n-hexyltriethoxysilane, methylcyclohexyldimethoxysilane, methylcyclohexyldiethoxysilane, n-octyltrimethoxysilane, n-octyltriethoxysilane, n-decyltrimethoxysilane, and n-decyltriethoxysilane.

Among the alkyl group-containing alkoxysilane compounds, n-decyltrimethoxysilane, dimethyldimethoxysilane, and n-octyltriethoxysilane are further preferable, in view of improving the dispersibility of the material to increase hardness in low temperatures, and n-decyltrimethoxysilane and n-octyltriethoxysilane are furthermore preferable, in view of the solubility in the material to increase hardness in low temperatures.

An alkoxysiloxane compound used as the compatible substance has two or more siloxane bonds, and has a structure in which at least one silicon atom has an alkoxy group. The alkoxysiloxane compound has a structure in which at least one of the silicon atoms constituting the siloxane bond has an organic substituent. The alkoxysiloxane compound, which has an alkoxy group and an organic substituent, can enhance the dispersibility of the material to increase hardness in low temperatures.

Examples of the alkoxy group and the organic substituent of the alkoxysiloxane compound include those described above for the alkoxysilane compound, and the alkoxysiloxane compound preferably has at least an alkyl group in view of enhancing the dispersibility of the material to increase hardness in low temperatures.

Examples of the alkoxysiloxane compound include methylmethoxysiloxane oligomer, methylphenylmethoxysiloxane oligomer, methylepoxymethoxysiloxane oligomer, methylmercaptomethoxysiloxane oligomer, and methylacryloylmethoxysiloxane oligomer.

The alkoxysiloxane compounds may be used singly or in combination of two or more.

Examples of the hydrocarbon solvent used as the compatible substance include aromatic hydrocarbon solvents. Among others, aromatic hydrocarbon solvents are preferable, in view of the compatibility to the matrix precursor such as curable silicone composition. Examples of the aromatic hydrocarbon solvents include aromatic hydrocarbon solvents having about 6 to 10 carbon atoms such as toluene, xylene, mesitylene, ethyl benzene, propyl benzene, butyl benzene, and t-butyl benzene, preferably toluene and xylene.

In the heat-conductive composition, the content of the compatible substance is preferably 6 parts by mass or more, more preferably 10 parts by mass or more, and further preferably 15 parts by mass or more, with respect to 100 parts by mass of a total of the matrix precursor and the material to increase hardness in low temperatures. Also, in the heat-conductive composition, the content of the compatible substance is preferably 60 parts by mass or less, more preferably 50 parts by mass or less, and further preferably 45 parts by mass or less, with respect to 100 parts by mass of a total of the matrix precursor and the material to increase hardness in low temperatures.

In the heat-conductive composition, the content of the compatible substance is preferably 6 to 60 parts by mass with respect to 100 parts by mass of a total of the matrix precursor and the material to increase hardness in low temperatures. When the content is 6 parts by mass or more, the uniformity when the material to increase hardness in low temperatures is mixed with the matrix precursor can be sufficiently enhanced. When the content is 60 parts by mass or less, effects according to the amount of the compatible substance used can be obtained. From these points of view, the content of the compatible substance is more preferably 10 to 50 parts by mass, further preferably 15 to 45 parts by mass.

The contents of the material to increase hardness in low temperatures and the heat-conductive filler in the heat-conductive composition are as described in the description of the heat-conductive sheet, and in the above, the content of each component is shown as an amount with respect to 100 parts by mass of the matrix, or a total of the matrix and the material to increase hardness in low temperatures, whereas, in the heat-conductive composition, it is shown as an amount with respect to 100 parts by mass of the matrix precursor, or a total of the matrix precursor and the material to increase hardness in low temperatures.

### (Step Y)

Step Y is the step of curing the heat-conductive composition. The heat-conductive composition may be cured by heating. The temperature when heating the heat-conductive composition is not specifically limited as long as the matrix precursor can be cured by heating. The temperature may be higher than room temperature (23° C.), and is preferably 50° C. or higher. Further, the heating temperature is not specifically limited and the heating temperature may be about a temperature at which the heat-conductive sheet and the heat-conductive composition are not thermally degraded, and is, for example, 180° C. or less, and preferably 150° C. or less. The heat-conductive composition may be heated in a single stage or in two or more stages. When heating in two or more stages, the heating temperature may fall within the aforementioned range in at least any one of the stages but preferably falls within the aforementioned range in all the stages. The total heating time is, for example, about 10 minutes to 3 hours. When heating in two or more stages, the heat-conductive composition may be semi-cured in the first stage, and the heat-conductive composition may be fully cured by heating in the second and subsequent stages, for example.

In the case where the heating of the second and subsequent stages is performed, some or all of the heating of the second and subsequent stages may be performed after step Z. In the case where a compatible substance is used, the compatible substance is easily volatilized from the heat-conductive composition by performing the heating of the second and subsequent stages after step Z.

In step Y, the heat-conductive composition may be molded into a predetermined shape, such as block form or sheet form, and also heated and cured. However, in view of easy cutting into a sheet form in step Z and enhancing orientation of the anisotropic filler, it is preferable to mold the composition into a block form.

In the case where the heat-conductive composition contains the anisotropic filler as the heat-conductive filler, the anisotropic filler is preferably oriented in one direction before the mixed composition is cured by heating in step Y. The anisotropic filler can be oriented by the magnetic field orientation method or the flow orientation method, and is preferably oriented by the magnetic field orientation method.

In the magnetic field orientation method, the heat-conductive composition may be injected into a mold or the like and placed in the magnetic field, and then the anisotropic filler may be oriented along the magnetic field. Then, an oriented molded product may be obtained by curing the matrix precursor. The heat-conductive composition may be cured under the heating conditions, as described above.

In the magnetic field orientation method, a release film may be disposed on the portion in contact with the heat-conductive composition in the mold. The release film to be used is, for example, a resin film having good releasability or a resin film having one side treated with a release agent. Use of a release film makes it easy to release the oriented molded product from the mold.

In the magnetic field orientation method, the viscosity of the heat-conductive composition to be used is preferably 10 to 300 Pa·s in view of orientation of the magnetic field. When it is 10 Pa·s or more, the heat-conductive filler is difficult to settle. When it is 300 Pa·s or less, the mixed composition has an improved fluidity to appropriately orient the anisotropic filler in the magnetic field, and thus the problems, such as the orientation taking too much time, do not arise. The viscosity is measured with a rotational viscometer (Brookfield viscometer DV-E, spindle SC4-14) at 25° C. and a rotational speed of 10 rpm.

In the case of using the heat-conductive filler difficult to settle or combining with an additive such as an anti-settling agent, the viscosity of the heat-conductive composition may be less than 10 Pa·s.

For the magnetic field orientation method, a superconducting magnet, a permanent magnet, an electromagnet, or the like can be mentioned as a magnetic force line source for applying the magnetic force lines. A superconducting magnet is preferable in view of generating a magnetic field with high magnetic flux density. The magnetic flux density of the magnetic field generated from such a magnetic force line source is preferably 1 to 30 tesla. When the magnetic flux density is 1 tesla or more, the anisotropic filler formed of carbon materials or the like can be easily oriented. When it is 30 tesla or less, practical production is enabled.

Magnetic field orientation may be performed typically in an environment at around room temperature, such as an environment of about 5 to 50° C., preferably about 15 to 40° C.

In the flow orientation method, a shear force is applied to the heat-conductive composition, to produce a primary sheet in which the anisotropic filler is oriented along the plane direction. More specifically, in the flow orientation method, the heat-conductive composition prepared in step X is first flattened and stretched while applying a shear force to form a sheet (primary sheet). The anisotropic filler can be oriented in the shearing direction by applying a shear force. For forming the sheet, the heat-conductive composition may be applied onto a base film, for example, using a coating applicator such as a bar coater and a doctor blade, or by extrusion molding or discharging from a nozzle, and then the applied heat-conductive composition may be dried, semi-cured, or full cured, as required. The thickness of the primary sheet is preferably about 50 to 5000 μm. In the primary sheet, the anisotropic filler is oriented in one direction along the plane direction of the sheet.

The heat-conductive composition used in the flow orientation method has a relatively high viscosity so that a shear force is applied when the composition is stretched into a sheet. Specifically, the viscosity of the heat-conductive composition is preferably 3 to 500 Pa·s.

The primary sheet may not be formed into a block, as will be discussed below, and then step Z may be performed. Alternatively, a laminate block (an oriented molded product in the form of a block) may be formed by layering a plurality of primary sheets so that the orientation directions coincide, and bonding the primary sheets to each other by hot press or the like while optionally heating for curing.

In the case of forming a laminate block, at least one of the surfaces of the primary sheets that are to face each other may be irradiated with vacuum ultraviolet rays before the primary sheets are layered. When the primary sheets are layered through the surface irradiated with vacuum ultraviolet rays, the primary sheets can be bonded each other firmly. In the case of irradiation with vacuum ultraviolet rays, the heat-conductive composition may be fully cured when producing the primary sheets, and curing by heating or the like is not necessary when the primary sheets are layered to form a laminate block.

Also in the flow orientation method, the heat-conductive composition may be cured under the heating conditions as described above.

The oriented molded product in the form of a block obtained through steps X and Y has the same features as the heat-conductive sheet, except that it is in the form of a block. In other words, the oriented molded product comprises the matrix, the material to increase hardness in low temperatures, and the heat-conductive filler, and may further comprise additives in addition to the above. The details of each of these components are as described for the heat-conductive sheet. The oriented molded product has a type OO hardness of 50 or less at 25° C., and a suitable range of type OO hardness is as described for the heat-conductive sheet.

### (Step Z)

The molded product (for example, oriented molded product) obtained by curing the heat-conductive composition in step Y is cut by slicing or other means in step Z to form a sheet-form molded product. Cutting of the molded product (that is, cured heat-conductive composition) may be performed in low temperature environment below room temperature. Since the material to increase hardness in low temperatures is blended, the heat-conductive composition of the present invention has increased hardness when cooled to a low temperature below room temperature. Therefore, processability is improved, and the sheet is prevented from being deformed by the pressing force caused by slicing and from having the orientation of the anisotropic filler disrupted, thereby obtaining a heat-conductive sheet with good quality.

Here, more specifically, the cutting in step Z may be performed after the oriented molded product is cooled to a temperature at which the type OO hardness is greater than 50. When cooled as described above, the hardness of the oriented molded product becomes sufficiently high to allow for easy slicing.

Specifically, the cutting in step Z may be performed in an environment at a temperature of 5 to −80° C. When the cutting is performed in the above environment, the cutting is performed in the state where the hardness of the molded product is moderately increased, which facilitates good processability in step Z. In view of sufficiently increasing hardness and improving processability, the cutting in step Z is performed in an environment at a temperature of preferably −5° C. or lower, more preferably −15° C. or lower, and further preferably −20° C. or lower.

Also, the cutting in step Z may be performed in an environment at a temperature of preferably −60° C. or higher, more preferably −50° C. or higher, and further preferably −45° C. or higher. When the temperature at the time of cutting is at or above such a lower limit value, step Z can be performed without the introduction of extensive equipment for cooling.

Performing cutting in an environment at the temperature described above means cooling the molded product to the temperature described above and then cutting the molded product in an atmosphere at the temperature described above. Further, the cutting blade itself used for cutting may also be cooled to the temperature described above before cutting the molded product.

Slicing in step Z may be performed with a known cutting blade, such as a shearing blade, for example. Here, in the case where the anisotropic filler is oriented in the molded product, it is preferable to perform the cutting along a direction that intersects with the orientation direction of the anisotropic filler. Cutting in this manner allows the anisotropic filler to be oriented in the thickness direction of the sheet. As a result of cutting such as slicing, the sheet-form products have the tips of the anisotropic filler exposed from the binder component in each surface that is a cut surface.

The sheet-form products obtained by cutting may be used as the heat-conductive sheet as they are or may be subjected to another treatment. For example, each surface that is a cut surface may be polished. The surface may be polished with polishing paper, for example. Furthermore, as described above, some or all of the heating of the second and subsequent stages may be performed after step Z. In the case where the heat-conductive composition contains a compatible substance, it is preferable to perform the heating of the first stage at a temperature which causes volatilization of a small amount of the compatible substance, and to volatilize the compatible substance by the heating of the second and subsequent stages.

The production method described above is one embodiment for obtaining the heat-conductive sheet, and the heat-conductive sheet may be obtained by methods other than the above. For example, the oriented molded product before cutting is not necessarily produced through step X and step Y, but may be produced by other methods.

### [Usage of Heat-Conductive Sheet]

The heat-conductive sheet of the present invention is used inside an electronic device or the like. The heat-conductive sheet is interposed between two members and is used to conduct heat from one member to the other member, for example. Specifically, the heat-conductive sheet is interposed between a heating element and a heat sink, to move heat generated in the heating element to the heat sink by heat conduction and dissipate the heat from the heat sink. Here, examples of the heating element include various electronic parts used inside electronic devices such as CPUs, power amplifiers, and power sources.

Examples of the heat sink include heat sinks, heat pumps, and metal housings of electronic devices. The heat-conductive sheet may be compressed with its two surfaces in close contact with the heating element and the heat sink, respectively, when use.

### EXAMPLES

Hereinafter, the present invention will be described in detail by way of examples, but the present invention is not limited at all to these examples.

The measurement methods and evaluation methods in Examples are as follows.

### [Melting Point]

The melting point of the material to increase hardness in low temperatures was measured with a TG-DTA system (manufactured by Shimadzu Corporation, simultaneous thermogravimetric and differential thermal analyzer “DTG-60”). Specifically, 20 mg of each material to increase hardness in low temperatures was weighed, and the melting point was estimated from the peak temperature of the DTA curve measured by increasing the temperature from −80 to 100° C. at 2° C./min under a nitrogen atmosphere.

### [Compatibility]

In the case where a compatible substance was used for the material to increase hardness in low temperatures in each of Examples and Comparative Examples, the compatibility was checked when the curable silicone composition was added to and mixed with the mixture of the compatible substance and the material to increase hardness in low temperatures, and evaluated according to the following evaluation criteria.
1: The material to increase hardness in low temperatures and the curable silicone composition were separated.
2: There was much cloudiness, but the material to increase hardness in low temperatures and the curable silicone composition were not separated.
3: There was slight cloudiness, but the material to increase hardness in low temperatures and the curable silicone composition were not separated.
4: There was minor cloudiness, but the material to increase hardness in low temperatures and the curable silicone composition were compatible with each other.
5: There was no cloudiness, and the material to increase hardness in low temperatures and the curable silicone composition were compatible with each other.

### [Hardness at 25° C.]

In each of Examples and Comparative Examples, the type OO hardness at 25° C. was measured in accordance with ASTM D2240 for a test piece in which 5 heat-conductive sheets with a thickness of 2 mm were overlapped.

### [Sliceability]

In each of Examples and Comparative Examples, the sliceability of an oriented molded product in the form of a block was evaluated at 25° C. and −40° C. using a shearing blade to slice it to a thickness of 0.3 mm according to the following evaluation criteria.
1: The molded product could not be sliced.
2: The molded product could be sliced, but the usable area was less than 50% due to deformation.
3: The molded product could be sliced, and the usable area was 50% or more and less than 70%.
4: The molded product could be sliced, and the usable area was 70% or more and less than 90%.
5: The molded product could be sliced without problems, and the usable area was 90% or more.

### [Change in Hardness]

In each of Examples and Comparative Examples, the change in hardness (increase in hardness) of the heat-conductive sheet when cooled from 25° C. to −40° C. was evaluated on a five-point scale from 1 to 5. The measurement of type OO hardness is the same as the above method for measuring hardness at 25° C.
1: There was a change by 4 points or less in type OO hardness.
2: There was a change by 5 to 10 points in type OO hardness.
3: There was a change by 11 to 19 points in type OO hardness.
4: There was a change by 20 to 34 points in type OO hardness.
5: There was a change by 35 points or more in type OO hardness.

### [Evaluation of Bleeding]

In each of Examples and Comparative Examples, a heat-conductive sheet with a thickness of 0.3 mm was left at 120° C. for 48 hours while compressed by 30% in the direction of thickness, and the change in weight of the heat-conductive sheet before and after being left for 48 hours was measured as the amount of bleeding. The amount of bleeding measured was evaluated according to the following evaluation criteria.

$$change in weight ( \% ) = ( initial weight - weight after test ) / initial weight$$

1: The change in weight was greater than 0.8%.
3: The change in weight was greater than 0.4% and 0.8% or less.
5: The change in weight was 0.4% or less.

The components used in Examples and Comparative Examples were as follows.

### (Matrix: Curable Silicone Composition)

Silicone base resin: alkenyl group-containing polyorganosiloxane
Silicone curing agent: Hydrogen polyorganosiloxane

### (Material to Increase Hardness in Low Temperatures)

Liquid paraffin: average molecular weight 400, density 0.852 g/cm³, kinematic viscosity at 40° C. 37 cSt
High melting point liquid silicone: linear high molecular weight silicone, kinematic viscosity at 25° C.: 3,000,000 cSt
Ester oil (ester compound): 2-ethylhexyl palmitate
Methyl phenyl silicone (kinematic viscosity at 25° C.: 125 cSt, refractive index n=1.49, specific gravity 1.065)
(Low molecular weight component other than material to increase hardness in low temperatures)
CPAO: Side-chain crystalline polyalphaolefin
Ethylene glycol

### (Heat-Conductive Filler)

Aluminum powder: spherical, average particle size 3 μmm, aspect ratio 1 to 1.5, thermal conductivity 230 W/m·K
Flaky graphite powder: average particle size 130 μm, aspect ratio 10 to 15, thermal conductivity 100 W/m·K
Graphitized carbon fiber: average fiber length 130 μm, aspect ratio 10, thermal conductivity 500 W/m·K

### (Compatible Substance)

n-Decyltrimethoxysilane

### Example 1

Liquid paraffin as the material to increase hardness in low temperatures and n-decyltrimethoxysilane as the compatible substance were mixed at 25° C. according to the formulation shown in Table 1, to obtain a mixture in which the material to increase hardness in low temperatures was dissolved in the compatible substance. The mixture obtained was uniformly mixed with the silicone base resin and the silicone curing agent as the curable silicone composition at 25° C. Thereafter, a minute amount (catalytic amount) of the catalyst (platinum catalyst) and then the heat-conductive filler were further added according to the formulation shown in Table 1, and the resultant was mixed at 25° C. to obtain a heat-conductive composition.

Subsequently, the heat-conductive composition was injected into a mold having a sufficiently larger thickness than the heat-conductive sheet, and an 8 T magnetic field was applied in the thickness direction in 25° C. environment to orient the anisotropic filler in the thickness direction. Thereafter, heating was carried out at 80° C. for 60 minutes to cure the curable silicone composition, to obtain an oriented molded product in the form of a block.

Then, in −40° C. environment, the oriented molded product in the form of a block was sliced into sheets using a shearing blade in the direction perpendicular to the direction in which the anisotropic filler was oriented, to obtain sheet-form molded products with thicknesses of 0.3 mm and 2 mm, and the sheet-form molded products were used as heat-conductive sheets. Then, the heat-conductive sheets obtained by further heating at 150° C. for 60 minutes were evaluated, and the evaluation results are shown in Table 1. In addition, during production, compatibility and sliceability at 25° C. and −40° C. were also evaluated. In the heat-conductive sheets obtained in the respective Examples and Comparative Examples, the anisotropic filler was oriented in the thickness direction, and the volume filling rate of the heat-conductive filler in the heat-conductive sheets was 62 vol %.

In each Example, the oriented molded product in the form of a block (heat-conductive sheet) had a type OO hardness of greater than 50 at −40° C. Also, the type OO hardness at 25° C. was the value shown in Table 1.

### Examples 2, 3, 5, 7, and 9

These examples were conducted in the same manner as in Example 1 except that the type of the material to increase hardness in low temperatures and the formulation for the components were changed to those shown in Table 1.

### Example 4

Liquid paraffin as the material to increase hardness in low temperatures was uniformly mixed with the silicone base resin and the silicone curing agent as the curable silicone composition at 25° C. Thereafter, a minute amount (catalytic amount) of the catalyst (platinum catalyst) and then the heat-conductive filler were further added according to the formulation shown in Table 1, and the resultant was mixed at 25° C. to obtain a heat-conductive composition. Then, the subsequent operation was conducted in the same manner as in Example 1 to produce heat-conductive sheets. The heat-conductive sheets obtained were evaluated in the same manner as in Example 1. Table 1 shows the evaluation results. In addition, during the production process, compatibility and sliceability at 25° C. and −40° C. were also evaluated.

### Examples 6, 8, and 10

These examples were conducted in the same manner as in Example 4 except that the type of the material to increase hardness in low temperatures was changed to those shown in Table 1.

### Comparative Examples 1 and 2

These comparative examples were conducted in the same manner as in Examples 2 and 4, respectively, except that CPAO was used instead of the material to increase hardness in low temperatures.

### Comparative Example 3

n-Decyltrimethoxysilane as the compatible substance was uniformly mixed with the silicone base resin and the silicone curing agent as the curable silicone composition at 25° C. according to the formulation shown in Table 1. Thereafter, a minute amount (catalytic amount) of the catalyst (platinum catalyst) and then the heat-conductive filler were further added according to the formulation shown in Table 1, and the resultant was mixed at 25° C. to obtain a heat-conductive composition. Then, the subsequent operation was conducted in the same manner as in Example 1 in an attempt to produce heat-conductive sheets. However, slicing was not possible at either 25° C. or −40° C., and heat-conductive sheets could not be obtained.

### Comparative Example 4

This comparative example was conducted in the same manner as in Example 1 to obtain a heat-conductive composition, except that ethylene glycol was used instead of the material to increase hardness in low temperatures and that the formulation was adjusted as shown in Table 1. Then, the subsequent operation was conducted in the same manner as in Example 1 in an attempt to produce heat-conductive sheets. However, slicing was not possible at either 25° C. or −40° C., and heat-conductive sheets could not be obtained.

In Comparative Examples 3 and 4, evaluation of hardness at 25° C. and change in hardness was conducted for the oriented molded product before slicing.

TABLE 1

| | | Ex- | Ex- | Ex- | Ex- | Ex- | Ex- | Ex- | Ex- |
|---|---|---|---|---|---|---|---|---|---|
| | | am- | am- | am- | am- | am- | am- | am- | am- |
| | | ple | ple | ple | ple | ple | ple | ple | ple |
| | | 1 | 2 | 3 | 4 | 5 | 6 | 7 | 8 |
| Formulation | Matrix | 18.9% | 17.0% | 12.0% | 20.0% | 17.0% | 17.0% | 17.0% | 20.0% |
| (mass %) | Material to | 0.2% | 2.0% | 7.0% | 2.0% | 2.0% | 2.0% | 2.0% | 2.0% |
| | increase hardness | | | | | | | | |
| | in low temperatures | | | | | | | | |
| | Aluminum powder | 45.0% | 45.0% | 45.0% | 50.0% | 45.0% | 52.0% | 45.0% | 50.0% |
| | Flaky graphite | 3.8% | 3.8% | 3.8% | 1.0% | 3.8% | 1.0% | 3.8% | 1.0% |
| | Graphitized carbon fiber | 28.0% | 28.0% | 28.0% | 27.0% | 28.0% | 28.0% | 28.0% | 27.0% |
| | n-Decyltrimethoxysilane | 4.1% | 4.2% | 4.2% | 0.0% | 4.2% | 0.0% | 4.2% | 0.0% |
| Material to | Type | Liquid paraffin | | | | High melting | | Ester oil | |
| increase | | | | | | point | | | |
| hardness | | | | | | liquid silicone | | | |
| in low | Melting point (° C.) | −15 | | | | −35 | | 2 | |
| temperatures | Alkyl group having 10 | Yes | Yes | Yes | Yes | No | No | Yes | Yes |
| | or more carbon atoms | | | | | | | | |
| | Dimethylsiloxane | No | No | No | No | Yes | Yes | No | No |
| | structure | | | | | | | | |
| Parts by mass of material to increase | | 0.95 | 11.8 | 58.3 | 10.0 | 11.8 | 11.8 | 11.8 | 10.0 |
| hardness in low temperatures with | | | | | | | | | |
| respect to 100 parts by mass of matrix | | | | | | | | | |
| Parts by | Anisotropic filler | 167 | 167 | 167 | 127 | 167 | 153 | 167 | 127 |
| mass with | Non-anisotropic filler | 236 | 237 | 237 | 227 | 237 | 274 | 237 | 227 |
| respect to 100 | Filler total | 403 | 404 | 404 | 355 | 404 | 426 | 404 | 355 |
| parts by mass | n-Decyltrimethoxysilane | 21.5 | 22.1 | 22.1 | 0.0 | 22.1 | 0.0 | 22.1 | 0.0 |
| of total of | | | | | | | | | |
| matrix and | | | | | | | | | |
| material to | | | | | | | | | |
| increase | | | | | | | | | |
| hardness | | | | | | | | | |
| in low | | | | | | | | | |
| temperatures | | | | | | | | | |
| Volume filling rate of heat-conductive | | 62% | 62% | 62% | 59% | 62% | 63% | 62% | 59% |
| filler with respect to total | | | | | | | | | |
| amount of heat-conductive sheet | | | | | | | | | |
| Evaluation | Compatibility | 5 | 5 | 5 | 4 | 5 | 5 | 5 | 4 |
| | Hardness at 25° C. | OO42 | OO35 | OO21 | OO43 | OO39 | OO48 | OO38 | OO46 |
| | Slicing at 25° C. | 1 | 1 | 1 | 2 | 1 | 2 | 1 | 2 |
| | Change in hardness | 2 | 4 | 5 | 4 | 4 | 4 | 4 | 4 |
| | from 25° C. to −40° C. | | | | | | | | |
| | Slicing at −40° C. | 3 | 5 | 5 | 5 | 5 | 5 | 5 | 5 |
| | Evaluation of bleeding | 5 | 5 | 3 | 5 | 5 | 5 | 5 | 5 |

| | | Ex- | Ex- | Com- | Com- | Com- | Com- |
|---|---|---|---|---|---|---|---|
| | | am- | am- | parative | parative | parative | parative |
| | | ple | ple | Exam- | Exam- | Exam- | Exam- |
| | | 9 | 10 | ple 1 | ple 2 | ple 3 | ple 4 |
| Formulation | Matrix | 17.0% | 20.0% | 17.0% | 20.0% | 19.0% | 17.0% |
| (mass %) | Material to | 2.0% | 2.0% | 2.0% | 2.0% | 0.0% | 2.0% |
| | increase hardness | | | | | | |
| | in low temperatures | | | | | | |
| | Aluminum powder | 45.0% | 50.0% | 45.0% | 50.0% | 45.0% | 45.0% |
| | Flaky graphite | 3.8% | 1.0% | 3.8% | 1.0% | 3.8% | 3.8% |
| | Graphitized carbon fiber | 28.0% | 27.0% | 28.0% | 27.0% | 28.0% | 28.0% |
| | n-Decyltrimethoxysilane | 4.2% | 0.0% | 4.2% | 0.0% | 4.2% | 4.2% |
| Material to | Type | Methyl | | CPAO | | None | Ethylene |
| increase | | phenyl | | | | | glycol |
| hardness | | silicone | | | | | |
| in low | Melting point (° C.) | −55 | | 50 | | — | |
| temperatures | Alkyl group having 10 | No | No | Yes | Yes | — | No |
| | or more carbon atoms | | | | | | |
| | Dimethylsiloxane | Yes | Yes | No | No | — | No |
| | structure | | | | | | |
| Parts by mass of material to increase | | 11.8 | 10.0 | 11.8 | 10.0 | 0.0 | 11.8 |
| hardness in low temperatures with | | | | | | | |
| respect to 100 parts by mass of matrix | | | | | | | |
| Parts by | Anisotropic filler | 167 | 127 | 167 | 127 | 167 | 167 |
| mass with | Non-anisotropic filler | 237 | 227 | 237 | 227 | 237 | 237 |
| respect to 100 | Filler total | 404 | 355 | 404 | 355 | 404 | 404 |
| parts by mass | n-Decyltrimethoxysilane | 22.1 | 0.0 | 22.1 | 0.0 | 22.1 | 22.1 |
| of total of | | | | | | | |
| matrix and | | | | | | | |
| material to | | | | | | | |
| increase | | | | | | | |
| hardness | | | | | | | |
| in low | | | | | | | |
| temperatures | | | | | | | |
| Volume filling rate of heat-conductive | | 62% | 59% | 62% | 59% | 62% | 62% |
| filler with respect to total | | | | | | | |
| amount of heat-conductive sheet | | | | | | | |
| Evaluation | Compatibility | 3 | 3 | 5 | 1 | — | 1 |
| | Hardness at 25° C. | OO38 | OO46 | OO75 | Not | OO46 | OO42 |
| | | | | | mol- | | |
| | | | | | dable | | |
| | Slicing at 25° C. | 1 | 2 | 5 | — | 1 | 1 |
| | Change in hardness | 3 | 3 | 1 | — | 1 | 1 |
| | from 25° C. to −40° C. | | | | | | |
| | Slicing at −40° C. | 3 | 4 | 5 | — | 1 | 1 |
| | Evaluation of bleeding | 1 | 1 | 3 | — | — | — |

In each of the above Examples, the use of a material to increase hardness in low temperatures having a predetermined structure and melting point resulted in good compatibility of the material to increase hardness in low temperatures with the matrix, and while the heat-conductive sheet was flexible at around room temperature, it was sufficiently hardened in low temperature environment. Therefore, the heat-conductive sheet can be cut and produced in low temperature environment, and high conduction efficiency can also be ensured at around normal temperature. Furthermore, the heat-conductive sheets of Examples 1 to 8, which each included a specific material to increase hardness in low temperatures, exhibited good reliability in long-term use, as bleeding was suppressed even when heated in a compressed state for a long period of time.

In contrast, although the heat-conductive sheets of Comparative Examples 1 and 2 each include a low molecular weight component (CPAO) instead of the material to increase hardness in low temperatures, they cannot be sufficiently flexible in room temperature environment due to its high melting point, making it difficult to ensure high conduction efficiency at around normal temperature.

Also, in Comparative Example 3, in which the material to increase hardness in low temperatures was not used, the design was made so as to be flexible in room temperature environment, but as a result, it remained flexible in low temperature environment as well. Thus, a molded product in the form of a block could not be processed not only in room temperature environment, but also in low temperature environment. In Comparative Example 4, although the low molecular weight component (ethylene glycol) was used instead of the material to increase hardness in low temperatures, this component had neither an alkyl group having 10 or more carbon atoms nor a dimethylsiloxane structure, and the compatibility thereof with the matrix was insufficient. Thus, the design was made so as to be flexible in room temperature environment, but as a result, it remained flexible in low temperature environment as well. Accordingly, the molded product in the form of a block could not be processed not only in room temperature environment, but also in low temperature environment.

1. A heat-conductive sheet comprising:
a matrix formed of polyorganosiloxane;
a material to increase hardness in low temperatures, the material having at least either one of an alkyl group having 10 or more carbon atoms and a dimethylsiloxane structure and also having a melting point of −60° C. to 23° C., thereby increasing a type OO hardness of the heat-conductive sheet, as specified in ASTM D2240, in a case where the heat-conductive sheet is cooled from room temperature to a temperature lower than room temperature; and
a heat-conductive filler,
the heat-conductive sheet having a type OO hardness of 50 or less at 25° C.

2. The heat-conductive sheet according to claim 1, wherein the material to increase hardness in low temperatures has a melting point of −40° C. to 5° C.

3. The heat-conductive sheet according to claim 1, wherein the material to increase hardness in low temperatures is at least one selected from the group consisting of a hydrocarbon compound, an ester compound, a high melting point liquid silicone, and a methyl phenyl silicone.

4. The heat-conductive sheet according to claim 3, wherein the hydrocarbon compound is liquid paraffin.

5. The heat-conductive sheet according to claim 1, wherein the heat-conductive sheet has a content of the material to increase hardness in low temperatures of 0.5 to 100 parts by mass, with respect to 100 parts by mass of the matrix.

6. The heat-conductive sheet according to claim 1, wherein the heat-conductive filler comprises an anisotropic filler.

7. A method for producing a heat-conductive sheet, the method comprising:
the step of obtaining an oriented molded product in a form of a block, the oriented molded product comprising: a matrix formed of polyorganosiloxane; a material to increase hardness in low temperatures, the material having at least either one of an alkyl group having 10 or more carbon atoms and a dimethylsiloxane structure and also having a melting point of −60° C. to 23° C., thereby increasing a type OO hardness of the oriented molded product, as specified in ASTM D2240, in a case where the oriented molded product is cooled from room temperature to a temperature lower than room temperature; and a heat-conductive filler; the oriented molded product having a type OO hardness of 50 or less at 25° C.; and
the step of cooling the oriented molded product so as to have a type OO hardness of greater than 50, and then cutting the oriented molded product.
